(19) United States
(12) Patent Application Publication
(10) Pub. No.: US 2024/0206144 A1
(43) Pub. Date: Jun. 20, 2024

(54) APPARATUS AND METHOD FOR MOUNTING COMPONENT

(71) Applicant: HANWHA PRECISION MACHINERY CO., LTD., Changwon-si (KR)

(72) Inventor: Eun Ho CHOI, Changwon-si (KR)

(73) Assignee: HANWHA PRECISION MACHINERY CO., LTD., Changwon-si (KR)

(21) Appl. No.: 18/594,563

(22) Filed: Mar. 4, 2024

Related U.S. Application Data
(63) Continuation of application No. PCT/KR22/02620, filed on Feb. 23, 2022.

(30) Foreign Application Priority Data
Sep. 2, 2021 (KR) 10-2021-0117049

(51) Int. Cl. H05K 13/08

(52) U.S. Cl. CPC H05K 13/0812; H05K 13/0882; H05K 13/089

(57) ABSTRACT

An apparatus for mounting a component includes: a head including a nozzle and a substrate recognition camera; a first correction camera generating a first image by capturing an image of a component adsorbed to the nozzle and disposed at a first height; a second correction camera generating a second image by capturing an image of the component adsorbed to the nozzle and disposed at a second height; and a controller obtaining a mounting offset of the component by comparing the first image and the second image with each other and controlling the head so that the component is mounted on the substrate in a state in which the mounting offset is applied.

### CROSS-REFERENCE TO RELATED APPLICATIONS

This application is a continuation of International Application No. PCT/KR2022/002620, filed on Feb. 23, 2022, in the Korean Intellectual Property Receiving Office, which is based on and claims priority to Korean Patent Application No. 10-2021-0117049, filed on Sep. 2, 2021, in the Korean Intellectual Property Office, the disclosure of which is incorporated herein in its entirety by reference.

### BACKGROUND

### 1 Field

Example embodiments of the disclosure relates to an apparatus and a method for mounting a component, and more particularly, to an apparatus and a method for mounting a component that obtain a mounting offset through simulated mounting in mounting a component on a substrate and then apply the mounting offset to mount the component in a state during actual mounting.

### 2. Description of Related Art

The surface mounting technology (SMT) collectively refers to technology of mounting or attaching a component on a surface of a printed circuit board (PCB).

Specifically, an SMT process refers to technology of printing solder paste on a PCB, mounting various surface mounting devices (SMD) on the PCB using a mounter apparatus, and then passing the PCB on which the surface mounting devices are mounted through a reflow oven to bond the PCB and leads of the surface mounting devices to each other.

An SMT line may relate to technology of producing completed PCBs through combination of a plurality of apparatuses, and depending on a work environment, one or more SMT lines including a plurality of apparatuses may be provided.

An SMT apparatus that mounts the component on the PCB may include a head which carries the component. Meanwhile, a posture of the head may deviate from a standard posture due to various factors. When the posture of the head deviates from the standard posture, the component may not be correctly carried and may not be mounted at a correct position on the PCB. In particular, in accordance with the trend toward miniaturization of the component, high precision in mounting the component has been required.

Accordingly, controlling the posture of the head properly so that the component is accurately mounted at a target position on the PCB has been demanded.

### SUMMARY

Various aspects of the disclosure provide an apparatus and a method for mounting a component that obtain a mounting offset through simulated mounting in mounting a component on a substrate and then apply the mounting offset to mount the component in a state of actual mounting.

However, the disclosure is not restricted to those set forth herein. The above and other aspects of the disclosure will become more apparent to one of ordinary skill in the art to which the disclosure pertains by referencing the detailed description of the embodiments given below.

According to an aspect of the disclosure, there is provided an apparatus for mounting a component, including: a head including at least one nozzle; a first correction camera generating a first image by capturing an image of a component adsorbed to the nozzle and disposed at a first height; a second correction camera generating a second image by capturing an image of the component adsorbed to the nozzle and disposed at a second height; and a controller calculating a mounting offset of the component by comparing the first image and the second image with each other and controlling the head so that the component is mounted on the substrate in a state in which the mounting offset is applied.

The second height may be lower than the first height.

The second height may correspond to a surface height of the substrate.

The controller may obtain the mounting offset using position displacement and posture displacement between an image of the component included in the first image and an image of the component included in the second image.

The controller may obtain the mounting offset by comparing at least one first image and at least one second image generated by capturing an image of the component at at least one preset angle with each other.

The controller may obtain the mounting offset by referring to a direction in which the head moves toward the second correction camera just before the second image is generated.

The second correction camera may capture an image of the component descending from the first height to the second height.

The nozzle adsorbing the component may ascend from the second height to the first height after the image of the component is captured by the second correction camera.

The mounting offset may include: a first mounting offset obtained using a posture of the component with respect to each of the at least one nozzle; and a second mounting offset obtained using a difference between a posture of the component at the first height and a posture of the component at the second height.

The controller may obtain a nozzle offset by referring to a posture of the nozzle with respect to at least one spindle supporting each of the at least one nozzle, obtain a camera offset by referring to a difference between a central axis of a substrate recognition camera capturing an image of the substrate in order to recognize the substrate and a preset central axis, and control the head so that the component is mounted on the substrate in a state in which the nozzle offset and the camera offset are applied.

According to another aspect of the disclosure, there is provided a method for mounting a component, including: generating a first image by capturing an image of a component adsorbed to a nozzle provided in a head and disposed at a first height; generating a second image by capturing an image of the component adsorbed to the nozzle and disposed at a second height; obtaining a mounting offset of the component by comparing the first image and the second image with each other; and controlling the head so that the component is mounted on a substrate in a state in which the mounting offset is applied.

The second height may be lower than the first height.

The second height may correspond to a surface height of the substrate.

The obtaining the mounting offset of the component may include obtaining the mounting offset using position displacement and posture displacement between an image of the component included in the first image and an image of the component included in the second image.

The obtaining the mounting offset of the component may include obtaining the mounting offset by comparing at least one first image and at least one second image generated by capturing an image of the component at at least one preset angle with each other.

The obtaining the mounting offset of the component may include obtaining the mounting offset by referring to a direction in which the head moves toward the second correction camera just before the second image is generated.

The second correction camera may capture an image of the component descending from the first height to the second height by a second correction camera generating the second image.

The nozzle adsorbing the component may ascend from the second height to the first height after the image of the component is captured by the second correction camera.

The mounting offset may include: a first mounting offset obtained using a posture of the component with respect to each of the at least one nozzle; and a second mounting offset obtained using a difference between a posture of the component at the first height and a posture of the component at the second height.

The method for mounting a component may further include: obtaining a nozzle offset by referring to a posture of the nozzle with respect to at least one spindle supporting each of the at least one nozzle; obtaining a camera offset by referring to a difference between a central axis of a substrate recognition camera capturing an image of the substrate to recognize the substrate and a preset central axis, and controlling the head so that the component is mounted on the substrate in a state in which the nozzle offset and the camera offset are applied.

Detailed contents of other embodiments are described in a detailed description and are illustrated in the drawings.

According to the apparatus and method for mounting a component according to the present disclosure as described above, it is possible to accurately dispose a component at a target position on a substrate by obtaining a mounting offset through simulated mounting and applying the mounting offset to mount the component in a state during actual mounting.

The effects of the present disclosure are not limited to the aforementioned effects, and other effects that are not mentioned may be obviously understood by one of ordinary skill in the art from the claims.

### BRIEF DESCRIPTION OF DRAWINGS

Example embodiments of the disclosure will be more clearly understood from the following detailed description taken in conjunction with the accompanying drawings, in which:

FIG. 1 illustrates an apparatus for mounting a component, according to one or more embodiments;

FIG. 2 illustrates a function of a conveyor, according to one or more embodiments;

FIG. 3 is a plan view illustrating that an image of a nozzle is captured by a first correction camera, according to one or more embodiments;

FIG. 4 is a side view illustrating that the image of the nozzle is captured by the first correction camera, according to one or more embodiments;

FIG. 5 is a plan view illustrating that an image of a substrate recognition camera is captured by the first correction camera, according to one or more embodiments;

FIG. 6 is a side view illustrating that the image of the substrate recognition camera is captured by the first correction camera, according to one or more embodiments;

FIG. 7 is a plan view illustrating that an image of a component is captured by a second correction camera, according to one or more embodiments;

FIG. 8 is a side view illustrating that the image of the component is captured by the second correction camera, according to one or more embodiments;

FIG. 9 illustrates that a component of a first image and a component of a second image are compared with each other, according to one or more embodiments;

FIG. 10 illustrates an image-capturing angle of a component by the second correction camera, according to one or more embodiments;

FIG. 11 illustrates that a mounting offset is obtained in consideration of a moving direction of a head, according to one or more embodiments; and

FIG. 12 is a flowchart for describing a method for mounting a component on a substrate using the apparatus for mounting a component, according to one or more embodiments.

### DESCRIPTION

Hereinafter, embodiments of the disclosure will be described in detail with reference to the accompanying drawings. The embodiments are example embodiments, and thus, the disclosure is not limited thereto and may be realized in various other forms. Advantages and features of the disclosure and methods for accomplishing these advantages and features will become apparent from embodiments to be described later in detail with reference to the accompanying drawings. However, these embodiments will be provided only in order to make the disclosure complete and allow one of ordinary skill in the art to completely recognize the scope of the disclosure, and the disclosure will be defined by the scope of the claims. Throughout the specification, the same components may be denoted by the same reference numerals.

Unless defined otherwise, all the terms (including technical and scientific terms) used herein have the same meaning as meanings commonly understood by one of ordinary skill in the art to which the present disclosure pertains. In addition, the terms defined in generally used dictionaries are not ideally or excessively interpreted unless they are specifically defined clearly.

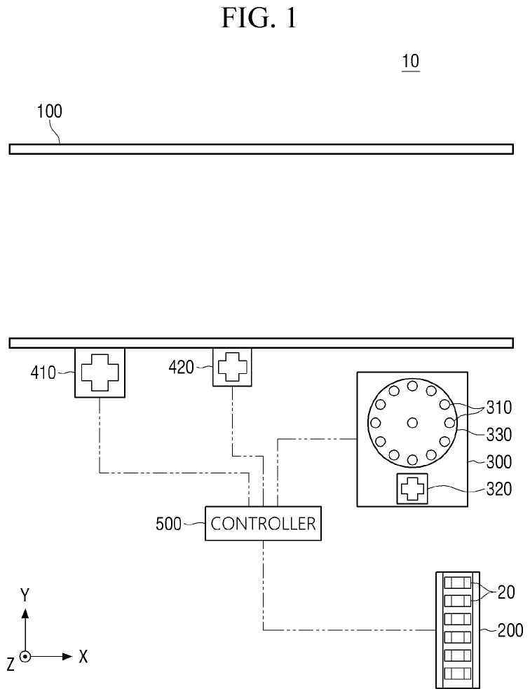

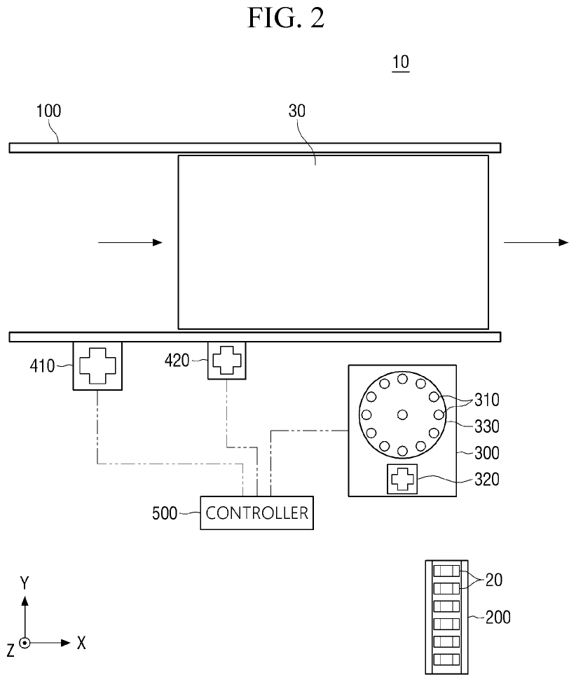

FIG. 1 illustrates an apparatus for mounting a component, according to one or more embodiments, and FIG. 2 illustrates a function of a conveyor, according to one or more embodiments.

Referring to FIG. 1, an apparatus 10 for mounting a component according to an embodiment includes a conveyor 100, a component supplier 200, a head 300, a first correction camera 410, and a second correction camera 420, and a controller 500.

The conveyor 100 may move a substrate 30. In the disclosure, the substrate 30 may be a printed circuit board (PCB). Hereinafter, a moving direction of the substrate 30 by the conveyor 100 is referred to as a first direction X, a direction parallel to the substrate 30 and perpendicular to the first direction X is referred to as a second direction Y, and a direction perpendicular to the first direction X and the second direction Y is referred to as a third direction Z. The controller 500 may be physically implemented by analog and/or digital circuits including one or more of a logic gate, an integrated circuit, a microprocessor, a microcontroller, a memory circuit, a passive electronic component, an active electronic component, an optical component, and the like, and may be configured to execute software and/or firmware stored in an internal memory or an external memory to perform the functions or operations described herein.

Referring to FIG. 2, the substrate 30 may be guided by the conveyor 100 to be moved to or removed from a working position. The conveyor 100 may sequentially move or remove different substrates 30 to or from the working position.

Referring to FIG. 1 again, the component supplier 200 may supply a component 20 to a working space. The component supplier 200 may sequentially supply a plurality of components 20. Although not illustrated, a plurality of component suppliers 200 may be provided. The plurality of component suppliers 200 may supply the same component 20 or different components 20.

The head 300 may mount the component 20 on the substrate 30. To this end, the head 300 may include a nozzle 310 and a substrate recognition camera 320.

The head 300 may move in the working space. For example, the head 300 may move on a two-dimensional plane formed by the first direction X and the second direction Y. The head 300 may move to the component supplier 200 to collect the component 20 or move to a position above a specific point of the substrate 30 to mount the component 20 at the specific point. A separate driver (not illustrated) may be provided in order to move the head 300.

The head 300 may include at least one nozzle 310. Hereinafter, it will be mainly described that a plurality of nozzles 310 are provided in the head 300. The plurality of nozzles 310 may be disposed in the head 300 in a circular shape about a central axis. The plurality of nozzles 310 may be provided in a nozzle body 330. The nozzle body 330 may rotate with respect to the head 300 about the central axis. As the nozzle body 330 rotates, a position of each nozzle 310 may change by a rotation angle. In order to dispose the nozzles 310 in positions and postures for mounting the component 20 on the substrate 30, the nozzle body 330 may rotate with respect to the head 300 by an appropriate rotation angle for each nozzle 310. A head body?

The substrate recognition camera 320 may capture an image of the substrate 30 to recognize the substrate 30. The substrate 30 may include a fiducial mark. The substrate recognition camera 320 may capture an image of the fiducial mark provided in the substrate 30. The captured image of the fiducial mark may be used to decide a position and a posture of the substrate 30 disposed at the working position. A mounting position and a mounting posture of the component 20 mounted on the substrate 30 may be determined based on the position and the posture of the substrate 30 decided through the fiducial mark.

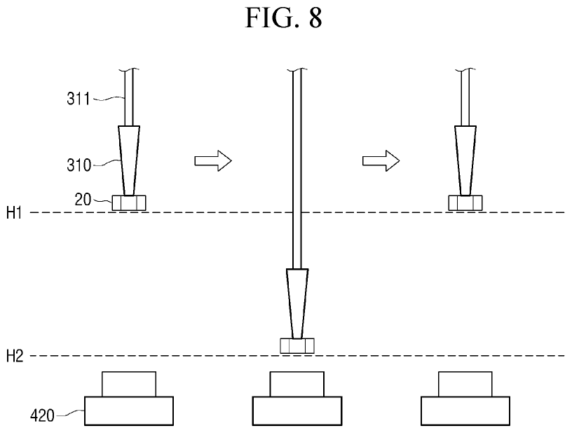

The first correction camera 410 may generate a first image by capturing an image of the component 20 adsorbed to the nozzle 310 and disposed at a first height H1 (see FIG. 8). Here, the first height H1 refers to a height with respect to a reference surface, and the reference surface may be, for example, a floor surface of the working space. The first height H1 may be a height of the component 20 when the head 300 moves in the working space.

The component 20 supplied from the component supplier 200 may be adsorbed to the nozzle 310. Before mounting the component 20 on the substrate 30, the head 300 may move to the first correction camera 410 to measure a posture of the component 20 adsorbed to the nozzle 310. In this case, a height of the component 20 may be the first height H1. The first correction camera 410 may generate the first image by capturing the image of the component 20 adsorbed to the nozzle 310. A posture of the component 20 included in the first image may be used to obtain a mounting offset.

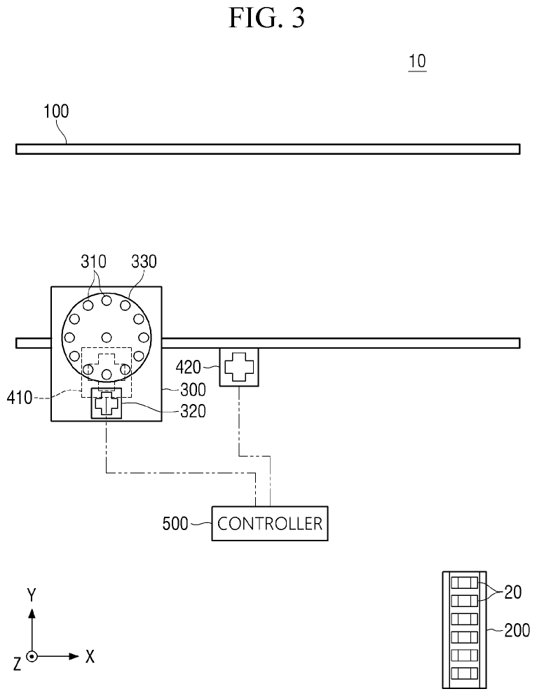

In addition, the first correction camera 410 may capture images of the nozzle 310 and the substrate recognition camera 320. The capturing of the images of the nozzle 310 and the substrate recognition camera 320 by the first correction camera 410 will be described in detail later with reference to FIGS. 3 to 6.

The second correction camera 420 may generate a second image by capturing an image of the component 20 adsorbed to the nozzle 310 and disposed at a second height H2 (see FIG. 8). Here, the second height H2 refers to a height with respect to the reference surface, and the reference surface may be, for example, the floor surface of the working space. The second height H2 may be lower than the first height H1. Specifically, the second height H2 may correspond to a surface height of the substrate 30.

In order to mount the component 20 on the substrate 30, the nozzle 310 may move from the head 300 toward the substrate 30. In this case, the component 20 may reach a surface of the substrate 30 while its height is being lowered to the second height H2. The second correction camera 420 may generate the second image by capturing an image of the component 20 descending from the first height H1 to the second height H2 before the component 20 is mounted on the substrate 30. A posture of the component 20 included in the second image may be used to obtain the mounting offset.

The posture of the component 20 adsorbed to the nozzle 310 may be decided using the first image generated by the first correction camera 410. Meanwhile, while the nozzle 310 moves from the head 300 toward the substrate 30, a posture of the nozzle 310 may change, and accordingly, the posture of the component 20 may change. The second image may be used to compensate for a displacement caused by such movement of the nozzle 310. By comparing the posture of the component 20 included in the first image and the posture the component 20 included in the second image with each other, it is possible to obtain the mounting offset in which the displacement caused by the movement of the nozzle 310 is compensated for.

The first correction camera 410 and the second correction camera 420 may be disposed adjacent to each other. In this case, the images of the component 20 by the first correction camera 410 and the second correction camera 420 may be captured continuously and quickly. Meanwhile, according to some embodiments, positions and disposition postures of the first correction camera 410 and the second correction camera 420 may be variously determined depending on an internal structure and a design environment of the apparatus 10 for mounting a component.

The controller 500 may perform overall control of the conveyor 100, the component supplier 200, the head 300, the first correction camera 410, and the second correction camera 420. In particular, the controller 500 may obtain the mounting offset of the component 20 by comparing the first image and the second image with each other, and control the head 300 such that the component 20 is mounted on the substrate 30 in a state in which the mounting offset is applied. The first image generated by the first correction camera 410 and the second image generated by the second correction camera 420 may be transferred to the controller 500. The controller 500 may obtain the mounting offset using a position displacement and a posture displacement between an image of the component 20 included in the first image and an image of the component 20 included in the second image.

In the embodiments, the mounting offset may include a first mounting offset and a second mounting offset. The first mounting offset is obtained using a posture of the component 20 with respect to the nozzle 310, and may be obtained using the first image. Here, the first mounting offset may be a deviation angle or distance between a predetermined portion of the component with respect to a predetermined portion of the nozzle 310. The second mounting offset is obtained using a difference between a posture of the component 20 at the first height H1 and a posture of the component 20 at the second height H2, and may be obtained by comparing the first image and the second image with each other.

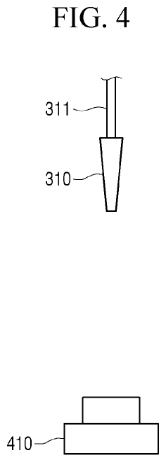

FIG. 3 is a plan view illustrating that an image of a nozzle is captured by a first correction camera, according to one or more embodiments, and FIG. 4 is a side view illustrating that the image of the nozzle is captured by the first correction camera, according to one or more embodiments.

Referring to FIGS. 3 and 4, the first correction camera 410 may capture an image of the nozzle 310. For the image of the nozzle 310 to be captured, the head 300 may move to a position above the first correction camera 410.

The image captured by the first correction camera 410 may be transferred to the controller 500. The controller 500 may decide a posture of the nozzle 310 by referring to the transferred image. For example, the controller 500 may decide a difference between a central axis of a spindle 311 supporting the nozzle 310 and a tip of the nozzle 310 to which the component 20 is adsorbed. The central axis of the spindle 311 may be preset to penetrate through a specific point of the substrate 30 to which the component 20 is adsorbed. For example, when the nozzle 310 descends in a state in which the nozzle 310 is positioned above a specific point of the substrate 30, the component 20 adsorbed to the nozzle 310 may be mounted at the specific point. Meanwhile, when a deviation exists between the central axis of the spindle 311 and the tip of the nozzle 310, the component 20 may not be mounted correctly at the specific point.

The controller 500 may obtain a nozzle offset by referring to a posture of the nozzle 310 with respect to the spindle 311. Here, the nozzle offset may be a deviation angle or distance between a predetermined portion of the nozzle 310 with respect to a predetermined portion of the spindle 311. The head 300 may include a plurality of nozzles 310. The controller 500 may obtain the nozzle offset for each of the plurality of nozzles 310 included in the head 300.

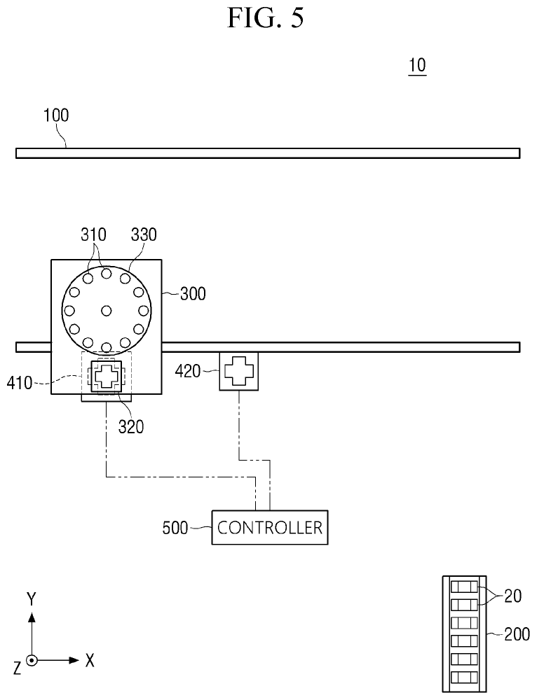

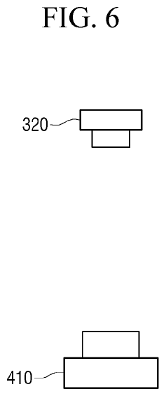

FIG. 5 is a plan view illustrating that an image of a substrate recognition camera is captured by the first correction camera, according to one or more embodiments, and FIG. 6 is a side view illustrating that the image of the substrate recognition camera is captured by the first correction camera, according to one or more embodiments.

Referring to FIGS. 5 and 6, the first correction camera 410 may capture an image of the substrate recognition camera 320. For the image of the substrate recognition camera 320 to be captured, the head 300 may move to a position above the first correction camera 410.

The image captured by the first correction camera 410 may be transferred to the controller 500. The controller 500 may decide a posture of the substrate recognition camera 320 by referring to the transferred image. For example, the controller 500 may decide a difference between a preset central axis of the substrate recognition camera 320 and a center axis of the substrate recognition camera 320 whose image is actually captured. The preset central axis may be set to penetrate through a specific point of the substrate 30 on which the fiducial mark is marked. For example, when an image of the substrate recognition camera 320 is captured in a state in which the substrate recognition camera 320 is positioned above the specific point of the substrate 30 on which the fiducial mark is marked, the fiducial mark may be displayed at the center of the image. Meanwhile, when there is a deviation between the preset central axis and the central axis of the substrate recognition camera 320, an outline of the substrate 30 may not be recognized correctly.

The controller 500 may obtain a camera offset by referring to the difference between the preset central axis and the central axis of the substrate recognition camera 320. Here, the camera offset may be a deviation angle or distance between the two axes.

The controller 500 may obtain the mounting offset by applying the nozzle offset and the camera offset along with the above-described first mounting offset and second mounting offset, and control the head 300 so that the component 20 is mounted based on the mounting offset. Accordingly, the component 20 may be mounted on the substrate 30 in a state in which various displacements and/or deviations that may occur during the movement of the component 20 from the component supplier 200 to the substrate 30 are compensated for.

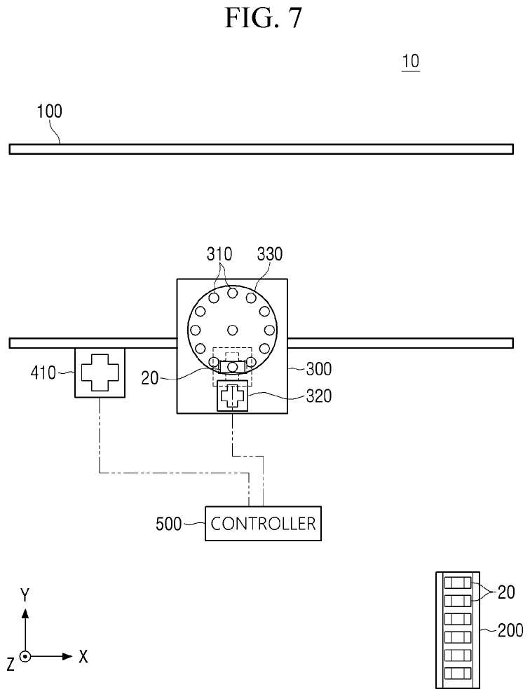

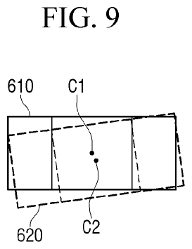

FIG. 7 is a plan view illustrating that an image of a component is captured by a second correction camera, according to one or more embodiments, FIG. 8 is a side view illustrating that the image of the component is captured by the second correction camera, according to one or more embodiments, and FIG. 9 illustrates that a component of a first image and a component of a second image are compared with each other, according to one or more embodiments.

Referring to FIGS. 7 and 8, the second correction camera 420 may capture an image of the component 20 adsorbed to the nozzle 310. For the image of the component 20 to be captured, the head 300 may move to a position above the second correction camera 420.

The image of the component 20 may be captured at the second height H2. As illustrated in FIG. 8, the second correction camera 420 may capture the image of the component 20 after the nozzle 310 descends from the first height H1 to the second height H2, and the nozzle 310 may ascend from the second height H2 to the first height H1 after the capturing of the image is completed. A moving direction of the nozzle 310 may be parallel to the third direction Z described above.

The image (the second image) captured by the second correction camera 420 may be transferred to the controller 500. The controller 500 may decide a displacement of the component 20 caused by descent movement of the nozzle 310 by referring to the transferred second image. For example, the controller 500 may obtain the second mounting offset using a position displacement and a posture displacement between the image of the component 20 included in the first image and the image of the component 20 included in the second image.

Referring to FIG. 9, the controller 500 may compare an image 610 (hereinafter referred to as a first image) of the component 20 included in the first image and an image (hereinafter referred to as a second image) 620 of the component 20 included in the second image with each other.

In order to compare the first image 610 and the second image 620 with each other, the controller 500 may perform scaling on at least one of the first image 610 and the second image 620. That is, the controller 500 may adjust a size of at least one of the first image 610 and the second image 620 so that the first image 610 and the second image 620 have the same size.

As illustrated in FIG. 9, a position displacement and a posture displacement may exist between the first image 610 and the second image 620. That is, the center C1 of the first image 610 and the center C2 of the second image 620 may be different from each other (position displacement), and disposition angles of the first image 610 and the second image 620 may be different from each other (posture displacement). The controller 500 may obtain the second mounting offset by referring to such differences.

The head 300 may include the plurality of nozzles 310. The controller 500 may obtain the second mounting offset for each of the plurality of nozzles 310 included in the head 300.

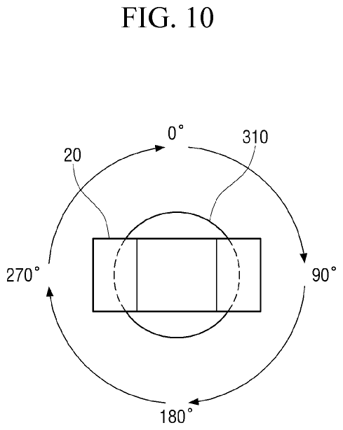

FIG. 10 illustrates an image-capturing angle of a component by the second correction camera, according to one or more embodiments.

Referring to FIG. 10, the controller 500 may obtain a mounting offset by comparing at least one first image and second image generated by capturing an image of the component 20 at least one preset angle with each other.

For example, the first correction camera 410 and the second correction camera 420 may generate images when the angle of the nozzle 310 is 0°, 90°, 180°, and 270°. The controller 500 may obtain a mounting offset by comparing the first image and the second image generated at 0° with each other and obtain a mounting offset by comparing the first image and the second image generated at 90° with each other, and may perform such process for 180° and 270°.

The first image and the second image may be different from each other for each angle due to the posture of the nozzle 310 with respect to the spindle 311 and various factors. For example, when referring to the first image and the second image generated when the angle of the nozzle 310 is 0°, an angular displacement formed between the component 20 in the first image and the component 20 in the second image may be a°, but when referring to the first image and the second image generated when the angle of the nozzle 310 is 90°, an angular displacement formed between the component 20 in the first image and the component 20 in the second image may be b° different from a°.

The mounting offset is provided for each angle of the nozzle 310, and accordingly, it becomes possible to more accurately mount the component 20.

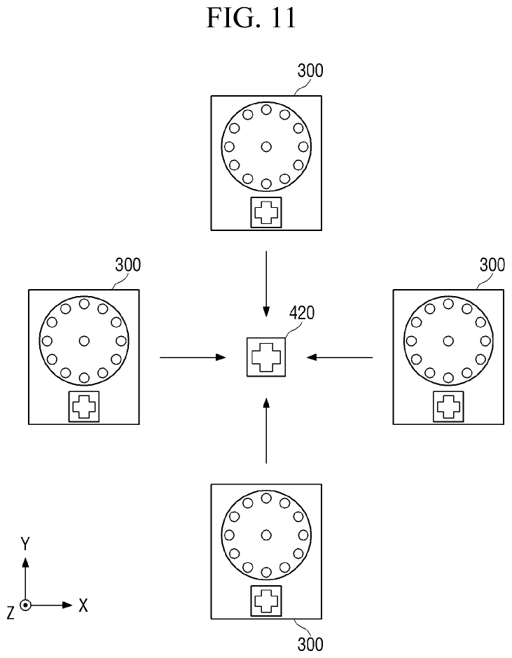

FIG. 11 illustrates that a mounting offset is obtained in consideration of a moving direction of a head, according to one or more embodiments.

Referring to FIG. 11, the controller 500 may obtain a mounting offset by referring to a direction in which the head 300 moves toward the second correction camera 420 just before the second image is generated.

When the head 300 moves in one direction, a posture of the nozzle 310 with respect to the head 300 may change to correspond to the one direction. In particular, when the head 300 is aged, a clearance between the head 300 and the nozzle 310 increases, such that a large posture displacement of the nozzle 310 with respect to the head 300 may be formed.

The mounting offset is obtained by referring to a moving direction of the head 300, and accordingly, the mounting position of the component 20 may be determined more accurately. For example, when the head 300 moves in an upward direction in order to mount a specific component, the posture of the nozzle 310 with respect to the head 300 may change to correspond to the upward direction. Specifically, the nozzle 310 can be angled upward relative to the head 300. The mounting offset is obtained by applying such posture displacement of the nozzle 310, and accordingly, precision in mounting the component may be improved.

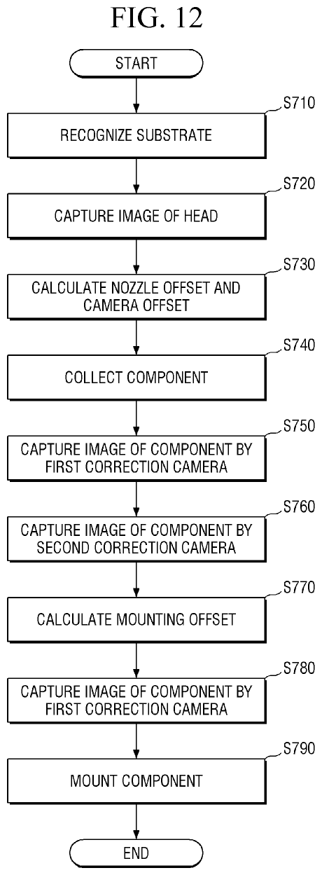

FIG. 12 is a flowchart for describing a method for mounting a component on a substrate using the apparatus for mounting a component, according to one or more embodiments.

Referring to FIG. 12, to mount the component 20 on the substrate 30, the controller 500 may first recognize the substrate 30 (S710).

To recognize the substrate 30, the head 300 may move to the substrate 30, and the substrate recognition camera 320 provided in the head 300 may capture an image of the fiducial mark marked on the substrate 30. The captured image may be transferred to the controller 500, and the controller 500 may recognize the substrate 30 by referring to the image.

When the recognition of the substrate 30 is completed, the first correction camera 410 may capture an image of the head 300 (S720). Specifically, the first correction camera 410 may capture images of the nozzle 310 and the substrate recognition camera 320 provided in the head 300. The captured images may be transferred to the controller 500, and the controller 500 may obtain a nozzle offset and a camera offset by referring to the images (S730).

The head 300 may collect the component 20 from the component supplier 200 (S740). For example, the nozzle 310 provided in the head 300 may adsorb the component 20 in a vacuum adsorption manner. When the component 20 is collected, the head 300 may move to the first correction camera 410.

The first correction camera 410 may capture an image of the component 20 (S750). The capturing of the image of the component 20 by the first correction camera 410 may be performed in a state in which the height of the component 20 is the first height H1. A first image captured by the first correction camera 410 may be transferred to the controller 500. The controller 500 may obtain a first mounting offset by referring to the first image. When the capturing of the image of the component 20 is completed, the head 300 may move to the second correction camera 420.

The second correction camera 420 may capture an image of the component 20 (S760). The capturing of the image of the component 20 by the second correction camera 420 may be performed in a state in which the height of the component 20 is the second height H2. A second image captured by the second correction camera 420 may be transferred to the controller 500. The controller 500 may obtain a second mounting offset by referring to the first image and the second image. In addition, the controller 500 may obtain a mounting offset by combining the first mounting offset and the second mounting offset (S770). In this case, the controller 500 may apply the nozzle offset and the camera offset in the mounting offset. When the capturing of the image of the component 20 is completed, the head 300 may move to the first correction camera 410.

The first correction camera 410 may capture an image of the component 20 again (S780). A posture of the nozzle 310 with respect to the head 300 may change while the head 300 moves between the first correction camera 410 and the second correction camera 420. To decide whether the posture of the nozzle 310 with respect to the head 300 has changed, the first correction camera 410 may capture the image of the component 20. The controller 500 may decide whether the posture of the nozzle 310 has changed, and apply the change in the posture of the nozzle 310 in the mounting of the component 20.

The head 300 may mount the component 20 on the substrate 30 (S790). The controller 500 may control the head 300 so as to apply the mounting offset.

Once the mounting offset is calculated, after the first correction camera 410 captures the image of the component 20, a process in which the second correction camera 420 captures an image the component 20 may be omitted. That is, after the first correction camera 410 captures the image of the component 20, the controller 500 may obtain a first mounting offset by referring to a newly generated first image, obtain a second mounting offset by referring to the newly generated first image and a previously generated second image, and control the head 300 so that the component 20 is mounted.

The capturing of the image of the component 20 by the second correction camera 420 may be performed periodically or performed by user's selection.

The embodiments have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it is to be understood that the embodiments described above are illustrative rather than being restrictive in all aspects.

What is claimed is:

1. An apparatus for mounting a component, comprising:
a head comprising at least one nozzle;
a first correction camera configured to generate a first image by capturing an image of a component adsorbed to the nozzle and disposed at a first height;
a second correction camera configured to generate a second image by capturing an image of the component adsorbed to the nozzle and disposed at a second height; and
a controller configured to obtain a mounting offset of the component by comparing the first image and the second image with each other, and control the head based on the mounting offset.

2. The apparatus for mounting a component of claim 1, wherein the second height is lower than the first height.

3. The apparatus for mounting a component of claim 1, wherein the second height corresponds to a surface height of the substrate.

4. The apparatus for mounting a component of claim 1, wherein the controller is configured to obtain the mounting offset using a position displacement and a posture displacement between an image of the component included in the first image and an image of the component included in the second image.

5. The apparatus for mounting a component of claim 1, wherein the controller is configured to obtain the mounting offset by comparing at least one first image and at least one second image generated by capturing an image of the component at at least one preset angle with each other.

6. The apparatus for mounting a component of claim 1, wherein the controller is configured to obtain the mounting offset by referring to a direction in which the head moves toward the second correction camera just before the second image is generated.

7. The apparatus for mounting a component of claim 1, wherein the second correction camera is configured to capture an image of the component descending from the first height to the second height.

8. The apparatus for mounting a component of claim 7, wherein the nozzle adsorbing the component is configured to ascend from the second height to the first height after the image of the component is captured by the second correction camera.

9. The apparatus for mounting a component of claim 1, wherein the mounting offset comprises:
a first mounting offset obtained using a posture of the component with respect to the at least one nozzle; and
a second mounting offset obtained using a difference between a posture of the component at the first height and a posture of the component at the second height.

10. The apparatus for mounting a component of claim 1, wherein the controller is configured to:
obtain a nozzle offset by referring to a posture of the nozzle with respect to at least one spindle supporting the at least one nozzle,
obtain a camera offset by referring to a difference between a central axis of a substrate recognition camera capturing an image of the substrate to recognize the substrate and a preset central axis, and
control the head on the substrate based on the nozzle offset and camera offset.

11. A method for mounting a component, comprising:
generating a first image by capturing an image of a component adsorbed to a nozzle provided in a head and disposed at a first height;
generating a second image by capturing an image of the component adsorbed to the nozzle and disposed at a second height;
obtaining a mounting offset of the component by comparing the first image and the second image with each other; and
controlling the head based on the mounting offset.

12. The method for mounting a component of claim 11, wherein the second height is lower than the first height.

13. The method for mounting a component of claim 11, wherein the second height corresponds to a surface height of the substrate.

14. The method for mounting a component of claim 11, wherein the obtaining the mounting offset of the component comprises obtaining the mounting offset using a position displacement and a posture displacement between an image of the component included in the first image and an image of the component included in the second image.

15. The method for mounting a component of claim 11, wherein the obtaining the mounting offset of the component comprises obtaining the mounting offset by comparing at least one first image and at least one second image generated by capturing an image of the component at least one preset angle with each other.

16. The method for mounting a component of claim 11, wherein the obtaining the mounting offset of the component comprises obtaining the mounting offset by referring to a direction in which the head moves toward a second correction camera generating the second image just before the second image is generated.

17. The method for mounting a component of claim 11, further comprising capturing an image of the component descending from the first height to the second height by a second correction camera generating the second image.

18. The method for mounting a component of claim 17, further comprising controlling the nozzle adsorbing the component to ascend from the second height to the first height after the image of the component is captured by a second correction camera a second correction camera generating the second image.

19. The method for mounting a component of claim 11, wherein the mounting offset comprises:
a first mounting offset obtained using a posture of the component with respect to the at least one nozzle; and
a second mounting offset obtained using a difference between a posture of the component at the first height and a posture of the component at the second height.

20. The method for mounting a component of claim 11, further comprising:
obtaining a nozzle offset by referring to a posture of the nozzle with respect to at least one spindle supporting the at least one nozzle;
obtaining a camera offset by referring to a difference between a central axis of a substrate recognition camera capturing an image of the substrate to recognize the substrate and a preset central axis, and
controlling the head on the substrate based on the nozzle offset and the camera offset.
